(19) United States
(12) Patent Application Publication
(10) Pub. No.: US 2024/0313171 A1
(43) Pub. Date: Sep. 19, 2024

(54) DISPLAY DEVICE AND METHOD OF FABRICATING THE SAME

(71) Applicant: Samsung Display Co., Ltd., Yongin-si (KR)

(72) Inventors: Hyung Il JEON, Yongin-si (KR); Jin Woo CHOI, Yongin-si (KR)

(21) Appl. No.: 18/537,548

(22) Filed: Dec. 12, 2023

(30) Foreign Application Priority Data
Mar. 16, 2023 (KR) 10-2023-0034429

(51) Int. Cl. H01L 33/50; H01L 23/00; H01L 25/065

(52) U.S. Cl. CPC H01L 33/507; H01L 24/13; H01L 24/16; H01L 25/0657; H01L 2224/13111; H01L 2224/13124; H01L 2224/13144; H01L 2224/13147; H01L 2224/16145; H01L 2225/06513; H01L 2924/12041; H01L 2933/0041

(57) ABSTRACT

A display device includes: a plurality of light emitting elements, each of the light emitting elements being spaced apart from each other and including a first semiconductor layer; a color adjustment layer on the light emitting elements; an organic layer between the light emitting elements and in a same layer as the first semiconductor layer and the color adjustment layer; and a first electrode contacting side surfaces of the first semiconductor layer and the color adjustment layer and enclosing the organic layer.

### CROSS-REFERENCE TO RELATED APPLICATION

This application claims priority to and the benefit of Korean Patent Application No. 10-2023-0034429, filed on Mar. 16, 2023, the entire disclosure of which is incorporated herein by reference.

### BACKGROUND

### 1. Field

Aspects of embodiments of the present disclosure relate to a display device and a method of fabricating the display device.

### 2. Description of Related Art

With the development of information technology, the importance of a display device, which is a connection medium between a user and information, has been emphasized.

### SUMMARY

Embodiments of the present disclosure provide a display device having an improved elongation rate between light emitting elements and a method of fabricating the display device.

According to embodiments of the present disclosure, a display device includes: a plurality of light emitting elements, each of the light emitting elements being spaced apart from each other and including a first semiconductor layer; a color adjustment layer on the light emitting elements; an organic layer between the light emitting elements and in a same layer as the first semiconductor layer and the color adjustment layer; and a first electrode contacting side surfaces of the first semiconductor layer and the color adjustment layer and enclosing the organic layer.

The display device may further include a first connection electrode spaced apart from the light emitting elements and contacting the first electrode.

The organic layer may include a flexible organic material.

Each of the light emitting elements may further include: an active layer on the first semiconductor layer; and a second semiconductor layer on the active layer.

The display device may further include: a second connection electrode on the second semiconductor layer; and a second electrode contacting the second connection electrode.

The display device may further include an insulating layer on the organic layer and the first electrode, and the insulating layer may contact side surfaces of the active layer and the second semiconductor layer.

The display device may further include an insulating layer on the first electrode and contacting side surfaces of the active layer and the second semiconductor layer.

The display device may further include a passivation layer on the color adjustment layer and the first electrode.

The color adjustment layer may have a porous structure.

The light emitting elements may include a first light emitting element in a first emission area, a second light emitting element in a second emission area, and a third light emitting element in a third emission area, and each of the first to the third light emitting elements may be configured to emit a third color of light.

The color adjustment layer may include: a first color adjustment layer on the first light emitting element and configured to convert the third color of light to a first color of light; a second color adjustment layer on the second light emitting element and configured to convert the third color of light to a second color of light; and a third color adjustment layer on the third light emitting element and configured to allow the third color of light to pass therethrough.

The first light emitting element and the first color adjustment layer may be defined as a first sub-pixel, the second light emitting element and the second color adjustment layer may be defined as a second sub-pixel, and the third light emitting element and the third color adjustment layer may be defined as a third sub-pixel, and one light emitting module may include the first sub-pixel, the second sub-pixel, and the third sub-pixel.

According to another embodiment of the present disclosure, a method of fabricating a display device includes: forming light emitting elements spaced apart from each other by etching a semiconductor material layer on a first substrate; forming, on the first substrate, an organic layer contacting a third semiconductor layer and a first semiconductor layer of each of the light emitting elements; forming an insulating layer to enclose the light emitting elements and the organic layer; forming a first connection electrode on the first substrate, and forming a second connection electrode on the light emitting elements; removing the first substrate and, then, forming a color adjustment layer by injecting a color adjustment material into the third semiconductor layer; and forming a first electrode configured to contact side surfaces of the first semiconductor layer and the color adjustment layer and to enclose the organic layer.

The semiconductor material layer may include: the third semiconductor layer; the first semiconductor layer on the third semiconductor layer; an active layer on the first semiconductor layer; and a second semiconductor layer on the active layer.

The method may further include forming a porous structure by etching the third semiconductor layer before the forming of the light emitting elements.

The first electrode may contact the first connection electrode.

The organic layer may include a flexible organic material.

The forming of the insulating layer may further include removing a portion of the insulating layer that contacts the organic layer.

The method may further include forming a passivation layer on the color adjustment layer and the first electrode.

The light emitting elements may be configured to emit a third color of light. The forming of the color adjustment layer may include: forming a first color adjustment layer by injecting a first color adjustment material into the third semiconductor layer in a first emission area, the first color adjustment material being configured to convert the third color of light to a first color of light; forming a second color adjustment layer by injecting a second color adjustment material into the third semiconductor layer in a second emission area, the second color adjustment material being configured to convert the third color of light to a second color of light; and forming a third color adjustment layer by injecting a third color adjustment material into the third semiconductor layer in a third emission area, the third color adjustment material being configured to allow the third color of light to pass through the third color adjustment layer.

### BRIEF DESCRIPTION OF THE DRAWINGS

The above and other aspects and features of the present disclosure will become more apparent by describing, in further detail, embodiments thereof with reference to the accompanying drawings, in which:

FIG. 1 is a plan view of a display device in accordance with an embodiment.

FIG. 2 is a sectional view of the display device shown in FIG. 1 taken along the line I-I′ of FIG. 1 in accordance with an embodiment.

FIG. 3 is a sectional view of the display device shown in FIG. 1 taken along the line I-I′ of FIG. 1 in accordance with an embodiment.

FIG. 4 is a sectional view of the display device shown in FIG. 1 taken along the line I-I′ of FIG. 1 in accordance with an embodiment.

FIG. 5 is a flowchart describing a method of fabricating a display device in accordance with an embodiment.

FIGS. 6 to 14 are sectional views illustrating steps of a method of fabricating the display device in accordance with an embodiment.

### DETAILED DESCRIPTION

The present disclosure now will be described more fully hereinafter with reference to the accompanying drawings, in which various embodiments thereof are shown. The present disclosure may, however, be embodied in many different forms, and should not be construed as limited to the embodiments described herein. Rather, these embodiments are provided so that this disclosure will be thorough and complete, and will fully convey the scope of the present disclosure to those skilled in the art.

It will be understood that when an element or layer is referred to as being “on”, “connected to” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. For example, the expression “at least one of a, b, and c” indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Hereinafter, embodiments of the present disclosure will be described in detail with reference to the accompanying drawings.

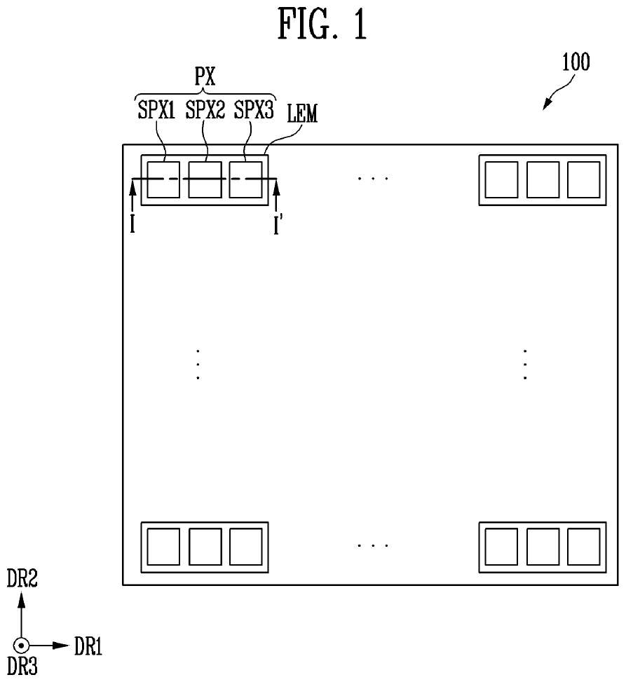

FIG. 1 is a plan view of a display device 100 in accordance with an embodiment.

Referring to FIG. 1, the display device 100 may be configured to output optical information (e.g., visual information).

For example, the display device 100 may be a device configured to display a video and/or a static image and may be applied to (or included in) various devices. The display device 100 may be formed of a rectangular panel having long sides extending in a first direction DR1 and short sides extending a second direction DR2 crossing (e.g., intersecting) the first direction DR1. Corners at where the long sides extending in the first direction DR1 and the short sides extending in the second direction DR2 meet may be rounded with a certain curvature (e.g., may be chamfered) or may be formed at a right angle. The plane shape of the display device 100 is not limited to a rectangular shape, and it may have other polygonal shapes, a circular shape, or an elliptical shape. The display device 100 may be formed to be planar, but it is not limited thereto. For example, the display device 100 may have a curved surface formed on each of left and right side edges thereof and may have a constant curvature or a varying curvature. In addition, the display device 100 may be formed to be flexible so that the display device 100 can be bent, curved, folded, or rolled.

The display device 100 may further include pixels PX configured to display an image, scan lines extending in the first direction DR1, and data lines extending in the second direction DR2. The pixels PX may be arranged in the form of a matrix in the first direction DR1 and the second direction DR2.

Each of the pixels PX may include sub-pixels SPX1, SPX2, and SPX3. Although FIG. 1 illustrates an embodiment in which each of the pixels PX includes three sub-pixels SPX1, SPX2, and SPX3 (i.e., a first sub-pixel SPX1, a second sub-pixel SPX2, and a third sub-pixel SPX3), embodiments of the present disclosure are not limited thereto.

The first sub-pixel SPX1, the second sub-pixel SPX2, and the third sub-pixel SPX3 may be connected to at least one data line from among the data lines and at least one scan line from among the scan lines.

Each of the first sub-pixel SPX1, the second sub-pixel SPX2, and the third sub-pixel SPX3 may have a rectangular shape, a square shape, or a rhombus shape in a plan view. For example, each of the first sub-pixel SPX1, the second sub-pixel SPX2, and the third sub-pixel SPX3 may have a rectangular planar shape having short sides extending in the first direction DR1 and long sides extending in the second direction DR2, as illustrated in FIG. 1. In another embodiment, each of the first sub-pixel SPX1, the second sub-pixel SPX2, and the third sub-pixel SPX3 may have a square or rhombus planar shape having sides having the same length with respect to the first direction DR1 and the second direction DR2.

The first sub-pixel SPX1, the second sub-pixel SPX2, and the third sub-pixel SPX3 may be arranged in (e.g., may be adjacent to each other in) the first direction DR1. In another embodiment, the first sub-pixel SPX1 and any one of the second sub-pixel SPX2 and the third sub-pixel SPX3 may be arranged in the first direction DR1, and the remaining one of the second sub-pixel SPX2 and the third sub-pixel SPX3 and the first sub-pixel SPX1 may be arranged in the second direction DR2.

In another embodiment, the second sub-pixel SPX2 and any one of the first sub-pixel SPX1 and the third sub-pixel SPX3 may be arranged in the first direction DR1, and the remaining one of the first sub-pixel SPX1 and the third sub-pixel SPX3 and the second sub-pixel SPX2 may be arranged in the second direction DR2. In another embodiment, the third sub-pixel SPX3 and any one of the first sub-pixel SPX1 and the second sub-pixel SPX2 may be arranged in the first direction DR1, and the remaining one of the first sub-pixel SPX1 and the second sub-pixel SPX2 and the third sub-pixel SPX3 may be arranged in the second direction DR2.

The first sub-pixel SPX1 may emit a first color of light. The second sub-pixel SPX2 may emit a second color of light. The third sub-pixel SPX3 may emit a third color of light. In one embodiment, the first color of light may correspond to light in a red wavelength band, the second color of light may correspond to light in a green wavelength band, and the third color of light may correspond to light in a blue wavelength band. The red wavelength band may be a wavelength band ranging from approximately 600 nm to approximately 750 nm. The green wavelength band may be a wavelength band ranging from approximately 480 nm to approximately 560 nm. The blue wavelength band may be a wavelength band ranging from approximately 370 nm to approximately 460 nm. However, embodiments of the present disclosure are not limited to the foregoing.

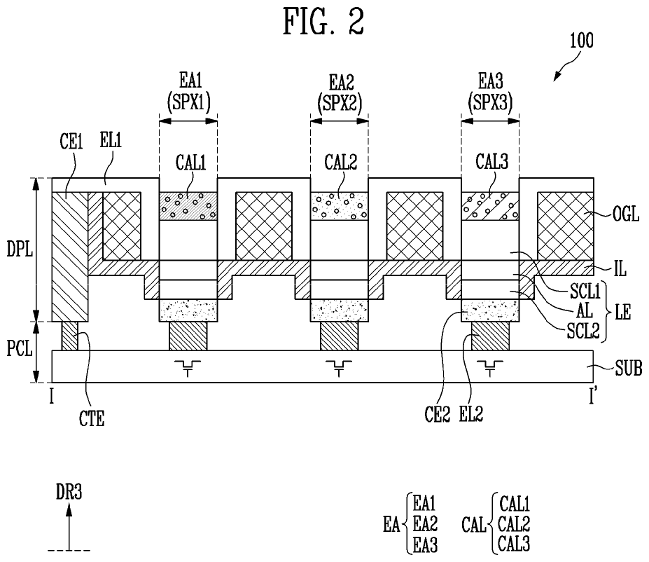

Referring to FIG. 2, the first sub-pixel SPX1 may form a first emission area EA1 from which the first color of light is emitted. The second sub-pixel SPX2 may form a second emission area EA2 from which the second color of light is emitted. The third sub-pixel SPX3 may form a third emission area EA3 from which the third color of light is emitted.

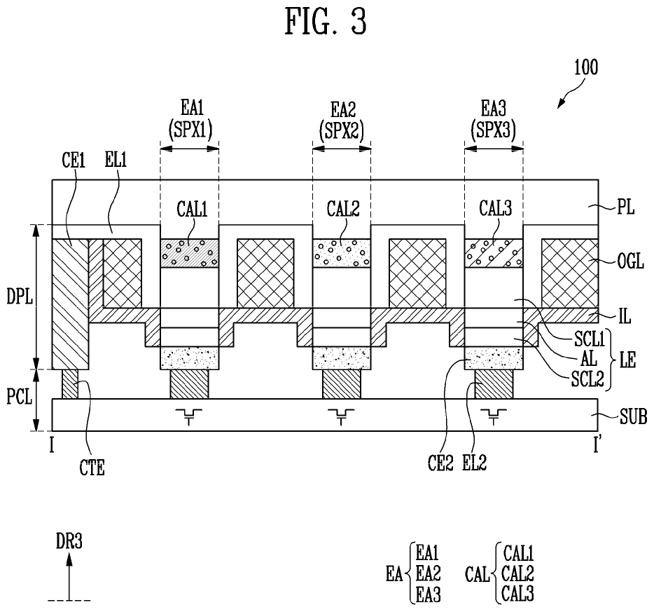

Each of the first sub-pixel SPX1, the second sub-pixel SPX2, and the third sub-pixel SPX3 may include an inorganic light emitting element having an inorganic semiconductor as a light emitting element LE (see, e.g., FIG. 3) to emit light.

As illustrated in FIG. 1, the surface area of the first sub-pixel SPX1, the surface area of the second sub-pixel SPX2, and the surface area of the third sub-pixel SPX3 may be substantially the same as each other, but embodiments of the present disclosure are not limited thereto. For example, the surface area of at least any one of the first sub-pixel SPX1, the second sub-pixel SPX2, and the third sub-pixel SPX3 may be different from another one. In another embodiment, the surface area of any two of the first sub-pixel SPX1, the second sub-pixel SPX2, and the third sub-pixel SPX3 may be substantially the same as each other, and the surface area of the remaining one sub-pixel may be different from the other two sub-pixels. In another embodiment, the surface area of the first sub-pixel SPX1, the surface area of the second sub-pixel SPX2, and the surface area of the third sub-pixel SPX3 may be different from each other.

In an embodiment, each of the pixels PX may be implemented as a single light emitting module LEM. For example, each of the pixels PX may be implemented in the form of a chip including the first sub-pixel SPX1, the second sub-pixel SPX2, and the third sub-pixel SPX3. Here, the chip may be implemented in the micro- or nano-size. In an embodiment in which each of the pixels PX is implemented as a single light emitting module LEM, an operation of transferring light emitting elements LE (see, e.g., FIG. 2) during a process of fabricating the display device 100 may be facilitated so that the production cost and time can be reduced.

FIG. 2 is a sectional view of the display device 100 taken along the line I-I′ of FIG. 1 in accordance with an embodiment.

Referring to FIG. 2, the display device 100 may include a pixel circuit layer PCL and a light-emitting-element layer DPL.

The pixel circuit layer PCL may include a substrate SUB, a contact electrode CTE, and second electrodes EL2.

The substrate SUB may form a base surface of the display device 100. Individual components of the display device 100 may be disposed on the substrate SUB. The substrate SUB may be a rigid substrate made of glass. In another embodiment, the substrate SUB may be a flexible substrate that is bendable, foldable, rollable, or the like. In such an embodiment, the substrate SUB may include an insulating material, such as a polymer resin, for example, polyimide.

Pixel circuits may be formed in the substrate SUB. Each of the pixel circuits may be connected to the corresponding second electrode EL2. Each of the pixel circuits may overlap the light emitting element LE in a third direction DR3 (e.g., in a thickness direction).

Each of the pixel circuits may include at least one transistor formed through a semiconductor process. Furthermore, each of the pixel circuits may further include at least one capacitor formed through a semiconductor process. For example, the pixel circuits each may include a complementary metal-oxide semiconductor (CMOS) circuit. The CMOS circuit may be a transistor formed by combining an n-channel metal-oxide-semiconductor field-effect transistor (nMOSFET) and a p-channel metal-oxide-semiconductor field-effect transistor (pMOSFET) with each other such that a synergy effect therebetween can be maximized and may be advantageous for improving the degree of integration with low power consumption. Each of the pixel circuits may apply a pixel voltage or an anode voltage to the corresponding second electrode EL2.

The second electrodes EL2 may be disposed on the corresponding pixel circuits. Each of the second electrodes EL2 may be an exposure electrode which is exposed from the pixel circuit. Each of the second electrodes EL2 may be integrally formed with the pixel circuit. Each of the second electrode EL2 may receive a pixel voltage or an anode voltage from the pixel circuit.

The second electrodes EL2 may include conductive material. For example, the second electrodes EL2 may include one or more selected from the group consisting of gold (Au), silver (Ag), aluminum (Al), molybdenum (Mo), chrome (Cr), titanium (Ti), nickel (Ni), neodymium (Nd), copper (Cu), and platinum (Pt). However, the present disclosure is not limited to the foregoing, and the second electrodes EL2 may include a transparent conductive oxide.

The contact electrode CTE may be disposed on the substrate SUB. The contact electrode CTE may include metal material for bonding the substrate SUB and a first connection electrode CE1 to each other. For example, the contact electrode CTE may include at least any one of gold (Au), copper (Cu), aluminum (AI), and tin (Sn). The contact electrode CTE may apply a common voltage or a cathode voltage to the first connection electrode CE1.

The light emitting element layer DPL may include second connection electrodes CE2, light emitting elements LE, a color adjustment layer CAL, an organic layer OGL, an insulating layer IL, a first electrode EL1, and the first connection electrode CE1.

Each of the second connection electrodes CE2 may be disposed on the corresponding second electrode EL2. Each of the second connection electrodes CE2 may be supplied with a pixel voltage or an anode voltage from the second electrode EL2. The second connection electrodes CE2 may each include at least any one of gold (Au), copper (Cu), aluminum (AI), and tin (Sn).

The light emitting element LE may be disposed on the pixel circuit layer PCL and spaced apart from each other. For example, each of the light emitting elements LE may be disposed on the corresponding second connection electrode CE2. Each of the light emitting elements LE may be supplied with a pixel voltage or an anode voltage from the second connection electrode CE2.

Each of the light emitting elements LE may be disposed in the corresponding emission area EA. For example, each of the light emitting elements LE may be disposed in the corresponding one of the first emission area EA1 formed to emit a first color of light, the second emission area EA2 formed to emit a second color of light, and the third emission area EA3 formed to emit a third color of light.

In an embodiment, the light emitting elements LE may emit the third color of light. Here, the light emitting element LE that is disposed in the first emission area EA1 may be referred to as a first light emitting element. The light emitting element LE that is disposed in the second emission area EA2 may be referred to as a second light emitting element. The light emitting element LE that is disposed in the third emission area EA3 may be referred to as a third light emitting element. In other words, the light emitting elements LE disposed in each emission area EA may emit the same third color of light. As described above, the third color of light may correspond to light in a blue wavelength band.

Each of the light emitting elements LE may include a first semiconductor layer SCL1, an active layer AL, and a second semiconductor layer SCL2. The second semiconductor layer SCL2, the active layer AL, and the first semiconductor layer SCL1 may be successively disposed in (e.g., may be stacked in) the third direction DR3.

The first semiconductor layer SCL1 may be disposed on the active layer AL. The first semiconductor layer SCL1 may include an N-type semiconductor. For example, the first semiconductor layer SCL1 may include one or more selected from the group consisting of InAlGaN, GaN, AlGaN, InGaN, AlN, and InN and may be doped with a first conductive dopant, such as Si, Ge, and Sn. However, the present disclosure is not limited to the foregoing examples.

The active layer AL may be disposed between the first semiconductor layer SCL1 and the second semiconductor layer SCL2. The active layer AL may have a single-quantum well structure or a multi-quantum well structure. The location of the active layer AL may be changed in various ways depending on the type of the light emitting element LE and is not limited to a specific example.

The second semiconductor layer SCL2 may be disposed on the active layer AL. The second semiconductor layer SCL2 may include a P-type semiconductor. For example, the second semiconductor layer SCL2 may include one or more semiconductor materials selected from the group consisting of InAlGaN, GaN, AlGaN, InGaN, AlN, and InN and may be doped with a second conductive dopant, such as Ga, B, and Mg. However, the present disclosure is not limited to the foregoing examples.

In an embodiment in which a voltage of a threshold voltage or more is applied between opposite ends of the light emitting element LE, an electron-hole pair may be recombined in the active layer AL, and the light emitting element LE may emit light. Because light emission of (or from) the light emitting element LE can be controlled based on the foregoing principle, the light emitting element LE may be used as a light source in various devices.

The color adjustment layer CAL may be disposed on the light emitting elements LE. For example, the color adjustment layer CAL may be disposed on the first semiconductor layer SCL1 of the light emitting elements LE. The color adjustment layer CAL may include a first color adjustment layer CAL1 disposed on the first semiconductor layer SCL1 in the first emission area EA1, a second color adjustment layer CAL2 disposed on the first semiconductor layer SCL1 in the second emission area EA2, and a third color adjustment layer CAL3 disposed on the first semiconductor layer SCL1 in the third emission area EA3.

The color adjustment layer CAL may adjust light emitted from the light emitting elements LE to a color of light.

For example, the first color adjustment layer CAL1 may convert the third color of light emitted from the light emitting element LE to the first color of light. The second color adjustment layer CAL2 may convert the third color of light emitted from the light emitting element LE to the second color of light. The third color adjustment layer CAL3 allows the third color of light emitted from the light emitting element LE to pass therethrough. Hence, the first color of light may be emitted from the first emission area EA1, the second color of light may be emitted from the second emission area EA2, and the third color of light may be emitted from the third emission area EA3. Each of the first color adjustment layer CAL1 and the second color adjustment layer CAL2 may be referred to as a color conversion layer. The third color adjustment layer CAL3 may be referred to as a color transmission layer.

The color adjustment layer CAL may include color adjustment substances dispersed in a matrix material.

The first color adjustment layer CAL1 may include first color adjustment substances for converting the third color of light emitted from the light emitting element LE to the first color of light. For example, the first color adjustment substances may include a plurality of first quantum dots dispersed in a matrix material, such as base resin. The first quantum dots may absorb the third color of light, shift the wavelength thereof according to an energy transition, and emit the first color of light.

The second color adjustment layer CAL2 may include second color adjustment substances for converting the third color of light emitted from the light emitting element LE to the second color of light. For example, the second color adjustment substances may include a plurality of second quantum dots dispersed in a matrix material, such as base resin. The second quantum dots may absorb the third color of light, shift the wavelength thereof according to an energy transition, and emit the second color of light.

The third color adjustment layer CAL3 may include third color adjustment substances allowing the third color of light emitted from the light emitting element LE to pass therethrough. For example, the third color adjustment substances may include scatterers for efficiently improving the third color of light. The scatterers may include one or more selected from the group consisting of silicon oxide (SiOₓ) (e.g., silica beads, hollow silica particles, or the like), titanium oxide (TiOₓ), zirconium oxide (ZrOₓ), aluminum oxide (AlₓO_{y}), indium oxide (InₓO_{y}), zinc oxide (ZnOₓ), tin oxide (SnOₓ), and antimony oxide (SbₓO_{y}). However, the present disclosure is not limited to the foregoing, and the third color adjustment layer CAL3 may include color conversion particles for converting a color of light to the third color of light.

The light emitting element LE and the first color adjustment layer CAL1 that are disposed in the first emission area EA1 may be defined as the first sub-pixel SPX1. The light emitting element LE and the second color adjustment layer CAL2 that are disposed in the second emission area EA2 may be defined as the second sub-pixel SPX2. The light emitting element LE and the third color adjustment layer CAL3 that are disposed in the third emission area EA3 may be defined as the third sub-pixel SPX3. Hence, each light emitting module LEM (see, e.g., FIG. 1) may include the first sub-pixel SPX1 configured to emit the first color of light, the second sub-pixel SPX2 configured to emit the second color of light, and the third sub-pixel SPX3 configured to emit the third color of light.

The organic layer OGL may be disposed on the insulating layer IL at a position spaced apart from the light emitting elements LE. In an embodiment, the organic layer OGL may be disposed in the same layer as the first semiconductor layer SCL1 and the color adjustment layer CAL. Furthermore, the organic layer OGL may be disposed between the light emitting element LE and the first connection electrode CE1.

The organic layer OGL may include flexible organic material. For example, the organic layer OGL may include at least one of a silicone-based polymer, polyurethane, polyurethane acrylate, acrylate polymer, and acrylate terpolymer. The silicone-based polymer may include polydimethylsiloxane (PDMS), hexamethyldisiloxane (HMDSO), or the like.

The organic layer OGL may have a flexible shape. For example, the organic layer OGL may be changed in shape by force applied thereto and may be elastically increased or reduced in length. An elongation rate between the light emitting elements LE may be enhanced by the organic layer OGL.

In an embodiment, the organic layer OGL may have a shape bent to be convex upwardly or downwardly by thermal contraction or the like. For example, in an embodiment in which the organic layer OGL has a shape that is bent to be convex downwardly, the shape of the organic layer OGL may be changed to a flat shape even by small force so that the organic layer OGL may increase in length, thereby enhancing the elongation rate between the light emitting elements LE.

The insulating layer IL may be disposed on the organic layer OGL and the first electrode EL1. The insulating layer IL may contact respective side surfaces of the active layer AL and the second semiconductor layer SCL2. Furthermore, the insulating layer IL may be disposed between the organic layer OGL and the first connection electrode CE1 such that the insulating layer IL contacts the organic layer OGL and the first connection electrode CE1. The insulating layer IL may passivate (e.g., may provide a planar surface over) the outer surface of the active layer AL and may include inorganic material. For example, the insulating layer IL may include one or more selected from the group consisting of silicon nitride (SiNₓ), silicon oxide (SiOₓ), silicon oxynitride (SiOₓN_{y}), and aluminum oxide (AlOₓ).

The first electrode EL1 may be disposed on the insulating layer IL to have a structure that encloses the organic layer OGL. The first electrode EL1 may contact a side surface of the first semiconductor layer SCL1. Furthermore, the first electrode EL1 may contact the first connection electrode CE1. Because the first semiconductor layer SCL1 corresponds to a structure patterned in each of the light emitting elements LE, the first electrode EL1 may apply, to the light emitting elements LE, a common voltage or a cathode voltage provided from the first connection electrode CE1.

The first electrode EL1 may contact a side surface of the color adjustment layer CAL. Hence, the first electrode EL1 may reflect light that is emitted from the color adjustment layer CAL and leaks sideways. In other words, the first electrode EL1 may reflect light and guide the light to be emitted toward the corresponding emission area EA1, EA2, or EA3 so that the light is blocked from reaching an adjacent emission area EA1, EA2, or EA3 and being mixed with other color light.

The first electrode EL1 may include conductive material. For example, the first electrode EL1 may include one or more selected from the group consisting of gold (Au), silver (Ag), aluminum (AI), molybdenum (Mo), chrome (Cr), titanium (Ti), nickel (Ni), neodymium (Nd), copper (Cu), and platinum (Pt). However, the present disclosure is not limited to the foregoing, and the first electrode EL1 may include a transparent conductive oxide.

The first connection electrode CE1 may be disposed to be spaced apart from the light emitting elements LE and may be disposed on the contact electrode CTE. Furthermore, the first connection electrode CE1 may contact the first electrode EL1. Hence, the first connection electrode CE1 may provide, to the first electrode EL1, a common voltage or a cathode voltage provided from the contact electrode CTE. The first connection electrode CE1 may include conductive material, such as metal.

FIG. 3 is a sectional view of the display device 100 taken along the line I-I′ of FIG. 1 in accordance with an embodiment.

In FIG. 3, descriptions of elements having reference numerals that are the same as in FIG. 2 refer to elements that are the same or substantially similar as described above with reference to FIG. 2 and repeated description thereof is omitted. Differences from FIG. 2 will be primarily described.

Referring to FIG. 3, the display device 100 may further include a passivation layer PL, which is disposed on the color adjustment layer CAL and the first electrode EL1. The passivation layer PL may cover the organic layer OGL as well as the color adjustment layer CAL. The passivation layer PL may prevent water or air from permeating an internal structure. Furthermore, the passivation layer PL may protect the internal structure from foreign substances, such as dust.

The passivation layer PL may include inorganic material or organic material.

In an embodiment in which the passivation layer PL includes inorganic material, the passivation layer PL may include at least one from among aluminum nitride (AlNₓ), silicon oxide (SiOₓ), silicon nitride (SiNₓ), silicon oxynitride (SiOₓN_{y}), zirconium oxide (ZrOₓ), hafnium oxide (HfOₓ), and titanium oxide (TiOₓ), but the present disclosure is not limited thereto.

In an embodiment in which the passivation layer PL includes organic material, the passivation layer PL may include at least one from among an acrylate resin, an epoxy resin, a phenolic resin, a polyamide resin, a polyimide resin, a polyester resin, a polyphenylene sulfide resin, and benzocyclobutene (BCB), but the present disclosure is not limited thereto.

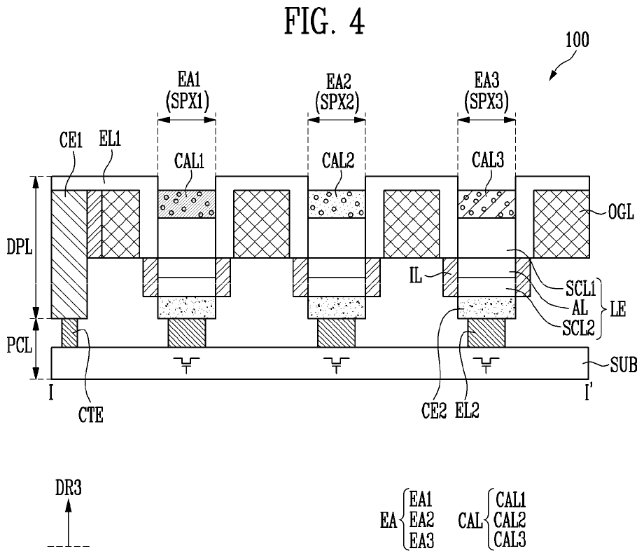

FIG. 4 is a sectional view of the display device 100 taken along the line I-I′ of FIG. 1 in accordance with an embodiment.

In FIG. 4, descriptions of elements having reference numerals that are the same as in FIG. 2 refer to elements that are the same or substantially similar as described above with reference to FIG. 2 and repeated description thereof is omitted. Differences from FIG. 2 will be primarily described.

Referring to FIG. 4, a portion of the insulating layer IL that is disposed on the organic layer OGL may be removed. The insulating layer IL is formed of material having a relatively low elongation rate. Hence, the elongation rate of the flexible organic layer OGL may be further enhanced by removing the portion of the insulating layer IL that contacts the organic layer OGL.

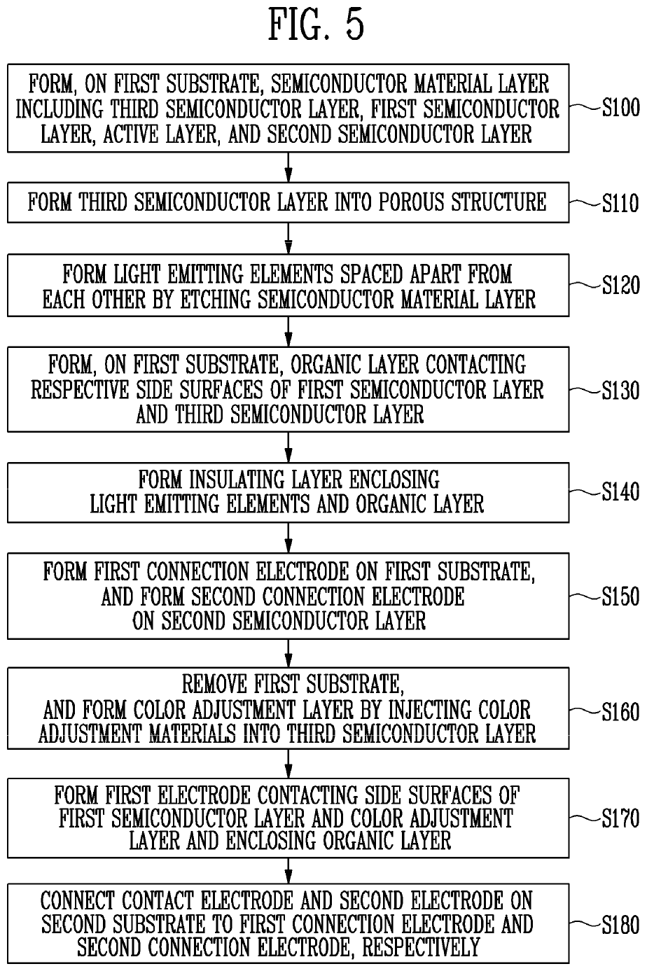

FIG. 5 is a flowchart describing a method of fabricating a display device in accordance with an embodiment.

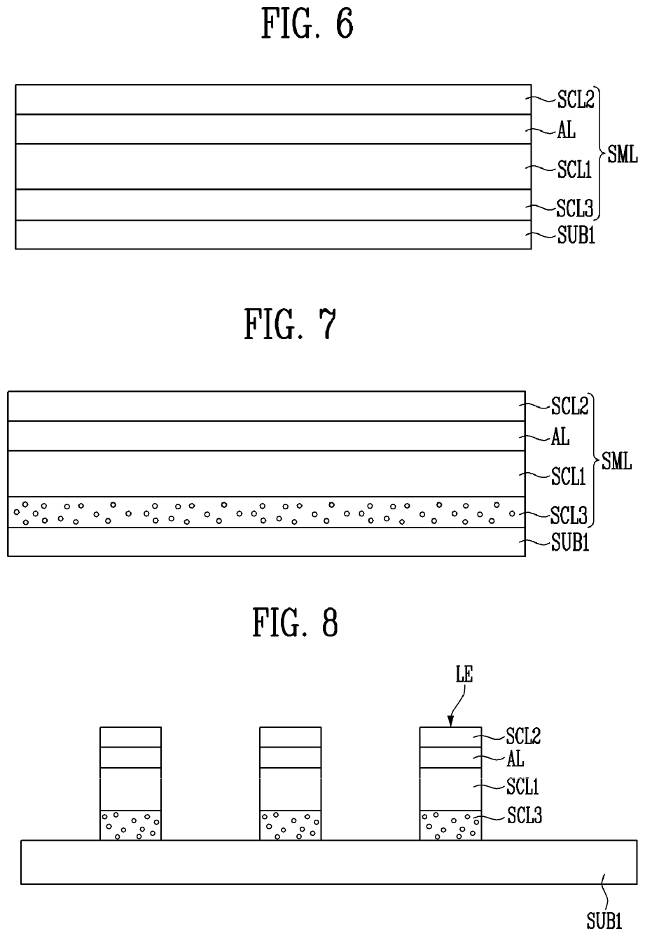

FIGS. 6 to 14 are sectional views illustrating steps of the method of fabricating the display device in accordance with an embodiment.

Referring to FIG. 5, the method of fabricating the display device may include step S100 of forming a semiconductor material layer including a third semiconductor layer, a first semiconductor layer, an active layer, and a second semiconductor layer on a first substrate, step S110 of forming the third semiconductor layer into a porous structure, step S120 of forming light emitting elements spaced apart from each other by etching the semiconductor material layer, step S130 of forming, on the first substrate, an organic layer contacting respective side surfaces of the first semiconductor layer and the third semiconductor layer, step S140 of forming an insulating layer configured to enclose the light emitting elements and the organic layer, step S150 of forming a first connection electrode on the first substrate and forming a second connection electrode on the second semiconductor layer, step S160 of removing the first substrate and, then, forming a color adjustment layer by injecting color adjustment materials into the third semiconductor layer, step S170 of forming a first electrode configured to contact respective side surfaces of the first semiconductor layer and the color adjustment layer and enclose the organic layer, and step S180 of respectively connecting a contact electrode and a second electrode on a second substrate to the first connection electrode and the second connection electrode.

Referring to FIGS. 5 and 6, at step S100, a semiconductor material layer SML is formed on a first substrate SUB1.

The first substrate SUB1 may be a base substrate provided to place (e.g., form or deposit) a target material thereon. The first substrate SUB1 may be a wafer for epitaxial growth of a desired material. For example, the first substrate SUB1 may be any one of a sapphire substrate, a GaAs substrate, a Ga substrate, and an InP substrate, but the present disclosure is not limited thereto. For example, if a specific material can satisfy a selectivity for fabricating the light emitting element LE (see, e.g., FIG. 8) and smoothly induce epitaxial growth of the desired material, the specific material may be selected as the material of the first substrate SUB1.

The semiconductor material layer SML may include a third semiconductor layer SCL3, a first semiconductor layer SCL1, an active layer AL, and a second semiconductor layer SCL2, which are successively (or sequentially) stacked on the first substrate SUB1. The first semiconductor layer SCL1, the active layer AL, and the second semiconductor layer SCL2 are the same as those described above; therefore, redundant explanation thereof will be omitted.

The third semiconductor layer SCL3 may include an N-type semiconductor identical to that of the first semiconductor layer SCL1 and may be a layer formed by over-doping an N-type semiconductor. The third semiconductor layer SCL3 may be formed by forming an undoped semiconductor layer on the first substrate SUB1, and then, over-doping the semiconductor layer with a first conductive dopant, such as Si, Ge, or Sn.

Referring to FIGS. 5 and 7, at step S110, the third semiconductor layer SCL3 may be formed into a porous structure. For example, the third semiconductor layer SCL3 may be formed into a porous structure by performing an electro-chemical etching process on the third semiconductor layer SCL3. In an embodiment, an oxalic acid solution may be used to perform the electro-chemical etching process, but the present disclosure is not limited thereto. The electro-chemical etching process may be performed so that the third semiconductor layer SCL3 may have a porous structure to which quantum dot material can be provided.

Referring to FIGS. 5 and 8, at step S120, the light emitting elements LE may be formed by etching the semiconductor material layer SML. For example, at step S120, a mask may be disposed on the semiconductor material layer SML such that the light emitting elements LE can be disposed at (e.g., formed at) positions spaced apart from each other. A patterning operation with nano-scale or micro-scale intervals may be performed through an etching process. The formed light emitting elements LE may emit the third color of light (e.g., blue light).

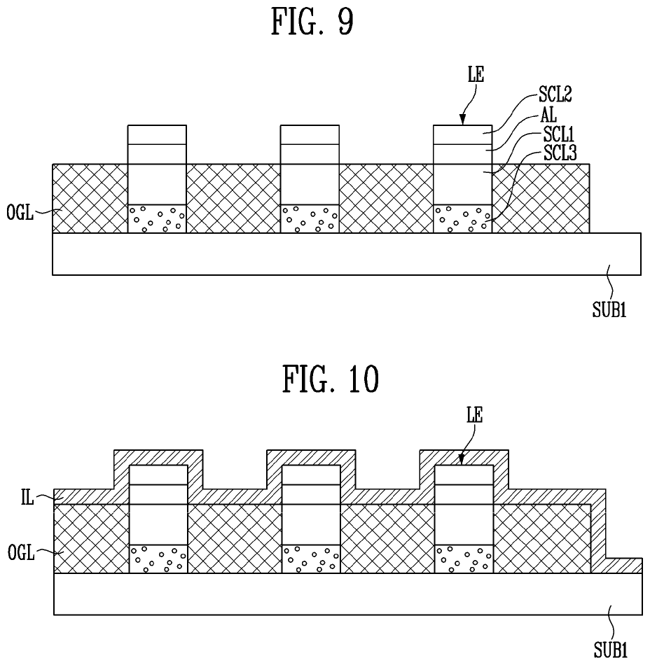

Referring to FIGS. 5 and 9, at step S130, the organic layer OGL may be formed on the first substrate SUB1. The organic layer OGL may be disposed between the light emitting elements LE and may be formed to contact the first semiconductor layer SCL1 and the third semiconductor layer SCL3. As illustrated in FIG. 9, the organic layer OGL may be formed to allow a portion of the first substrate SUB1 to be exposed for formation of the first connection electrode CE1, to be described below.

Referring to FIGS. 5 and 10, at step S140, the insulating layer IL may be formed to enclose (e.g., to cover) the light emitting elements LE and the organic layer OGL. Furthermore, the insulating layer IL may also be formed in an exposed area (e.g., may also be formed on an exposed surface) of the first substrate SUB1.

In an embodiment, step S140 may further include the step of removing a portion of the insulating layer IL that contacts the organic layer OGL. The insulating layer IL is formed of material having a relatively low elongation rate, so the elongation rate of the flexible organic layer OGL may be further enhanced by removing the portion of the insulating layer IL that contacts the organic layer OGL (see, e.g., FIG. 4).

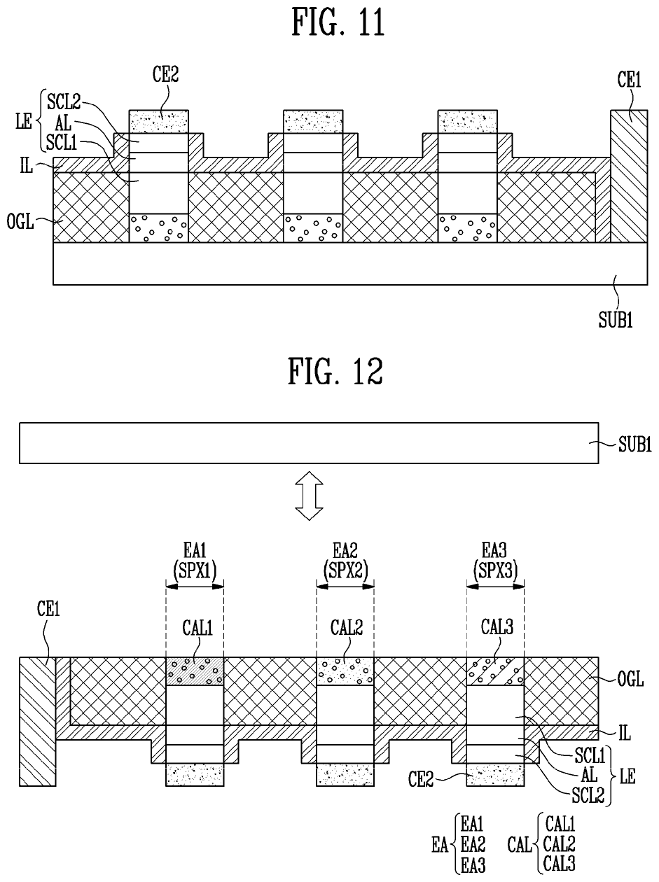

Referring to FIGS. 5 and 11, at step S150, the first connection electrode CE1 may be formed on the first substrate SUB1, and a second connection electrode CE2 may be formed on the second semiconductor layer SCL2. To this end, a process of removing portions of the insulating layer IL that are disposed on the first substrate SUB1 and the second semiconductor layer SCL2 may be performed before the first connection electrode CE1 and the second connection electrode CE2 are formed.

Referring to FIGS. 5 and 12, at step S160, the first substrate SUB1 may be removed (or separated) from the third semiconductor layer SCL3, the organic layer OGL, the insulating layer IL, and the first connection electrode CE1. Thereafter, color adjustment materials may be injected into the third semiconductor layer SCL3 to form color adjustment layers CAL. Here, because each of the color adjustment materials is injected into the corresponding third semiconductor layer SCL3, which has a porous structure, the color adjustment layers CAL may be concurrently (or simultaneously) formed, such that the process convenience can be enhanced. Furthermore, the color adjustment layer CAL having a porous structure is disposed adjacent to the light emitting elements LE so that the color reproducibility can be enhanced.

In an embodiment, step S160 may include the step of forming a first color adjustment layer CAL1 by injecting a first color adjustment material into the third semiconductor layer SCL3 that is disposed in the first emission area EA1, the step of forming a second color adjustment layer CAL2 by injecting a second color adjustment material into the third semiconductor layer SCL3 that is disposed in the second emission area EA2, and the step of forming a third color adjustment layer CAL3 by injecting scatterers into the third semiconductor layer SCL3 that is disposed in the third emission area EA3.

Accordingly, the first color adjustment layer CAL1 may convert the third color of light emitted from the light emitting element LE to the first color of light. The second color adjustment layer CAL2 may convert the third color of light emitted from the light emitting element LE to the second color of light. The third color adjustment layer CAL3 allows the third color of light emitted from the light emitting element LE to pass therethrough.

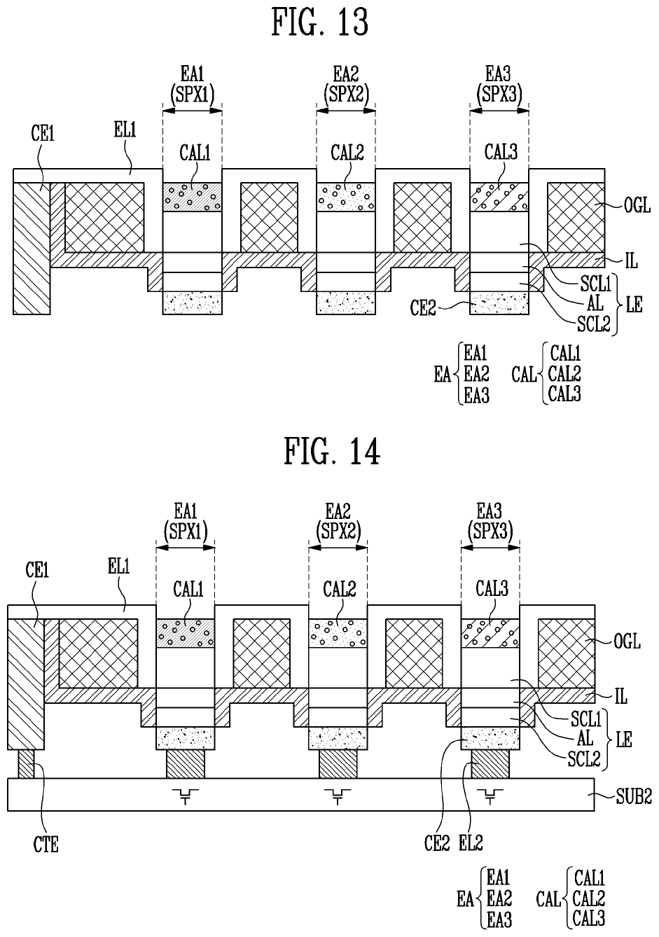

Referring to FIGS. 5 and 13, at step S170, a first electrode EL1 may be formed to contact respective side surfaces of the first semiconductor layer SCL1 and the color adjustment layer CAL and to enclose (e.g., cover) the organic layer OGL. Furthermore, the first electrode EL1 may contact the first connection electrode CE1 disposed on a side surface thereof. To this end, a process of removing portions of the organic layer OGL that contact the side surfaces of the first semiconductor layer SCL1 and the color adjustment layer CAL may be performed first. Here, the organic layer OGL may be removed by a thickness of the first electrode EL1. Hence, the first electrode EL1 may provide a common voltage or a cathode voltage provided from the first connection electrode CE1 to the first semiconductor layer SCL1 of each of the light emitting elements LE.

In an embodiment, after step S170, the step of forming the passivation layer PL on the color adjustment layer CAL and the first electrode EL1 may be selectively performed (see, e.g., FIG. 3).

Here, a structure fabricated through steps S100 to S170 (see, e.g., FIG. 13) may be defined as one light emitting module LEM (see, e.g., FIG. 1). In other words, each light emitting module LEM may include the first sub-pixel SPX1 configured to emit the first color of light, the second sub-pixel SPX2 configured to emit the second color of light, and the third sub-pixel SPX3 configured to emit the third color of light.

Referring to FIGS. 5 and 14, at step S180, the light emitting module LEM may be transferred onto the second substrate SUB2. In other words, the contact electrode CTE and the second electrode EL2 on the second substrate SUB2 may be respectively connected to the first connection electrode CE1 and the second connection electrode CE2. As such, in an embodiment in which the transfer process is performed by using the light emitting module LEM including the first sub-pixel SPX1, the second sub-pixel SPX2, and the third sub-pixel SPX3, the transfer process may be facilitated, and the processing time may be reduced compared to a case in which the sub-pixels SPX1, SPX2, and SPX3 are individually transferred.

Various embodiments of the present disclosure provide a display device having an improved elongation rate between light emitting elements and a method of fabricating the display device.

However, aspects and features of the present disclosure are not limited to those described above, and various other aspects and features would be understood by one of ordinary skill in the art within the spirit and scope of the present disclosure.

The embodiments described in detail above are provided to explain the present disclosure, but these embodiments are not intended to limit the scope of the present disclosure. It should be understood by those skilled in the art that various changes, substitutions, and alternations may be made therein without departing from the scope of the disclosure as defined by the following claims and their equivalents.

The scope of the present disclosure is not limited by detailed descriptions of the present specification and should be defined by the accompanying claims and their equivalents. Furthermore, all changes or modifications of the present disclosure derived from the claims, and equivalents thereof, should be construed as being included in the scope of the present disclosure. The embodiments may be combined to form additional embodiments.

What is claimed is:

1. A display device comprising:
a plurality of light emitting elements, each of the light emitting elements being spaced apart from each other and comprising a first semiconductor layer;
a color adjustment layer on the light emitting elements;
an organic layer between the light emitting elements and in a same layer as the first semiconductor layer and the color adjustment layer; and
a first electrode contacting side surfaces of the first semiconductor layer and the color adjustment layer and enclosing the organic layer.

2. The display device according to claim 1, further comprising a first connection electrode spaced apart from the light emitting elements and contacting the first electrode.

3. The display device according to claim 1, wherein the organic layer comprises a flexible organic material.

4. The display device according to claim 1, wherein each of the light emitting elements further comprises:
an active layer on the first semiconductor layer; and
a second semiconductor layer on the active layer.

5. The display device according to claim 4, further comprising:
a second connection electrode on the second semiconductor layer; and
a second electrode contacting the second connection electrode.

6. The display device according to claim 4, further comprising an insulating layer on the organic layer and the first electrode, the insulating layer contacting side surfaces of the active layer and the second semiconductor layer.

7. The display device according to claim 4, further comprising an insulating layer on the first electrode and contacting side surfaces of the active layer and the second semiconductor layer.

8. The display device according to claim 1, further comprising a passivation layer on the color adjustment layer and the first electrode.

9. The display device according to claim 1, wherein the color adjustment layer has a porous structure.

10. The display device according to claim 1, wherein the light emitting elements comprise a first light emitting element in a first emission area, a second light emitting element in a second emission area, and a third light emitting element in a third emission area, and
wherein each of the first to the third light emitting elements is configured to emit a third color of light.

11. The display device according to claim 10, wherein the color adjustment layer comprises:
a first color adjustment layer on the first light emitting element and configured to convert the third color of light to a first color of light;
a second color adjustment layer on the second light emitting element and configured to convert the third color of light to a second color of light; and
a third color adjustment layer on the third light emitting element and configured to allow the third color of light to pass therethrough.

12. The display device according to claim 11, wherein the first light emitting element and the first color adjustment layer are defined as a first sub-pixel, the second light emitting element and the second color adjustment layer are defined as a second sub-pixel, and the third light emitting element and the third color adjustment layer are defined as a third sub-pixel, and
wherein one light emitting module comprises the first sub-pixel, the second sub-pixel, and the third sub-pixel.

13. A method of fabricating a display device, the method comprising:
forming light emitting elements spaced apart from each other by etching a semiconductor material layer on a first substrate;
forming, on the first substrate, an organic layer contacting a third semiconductor layer and a first semiconductor layer of each of the light emitting elements;
forming an insulating layer to enclose the light emitting elements and the organic layer;
forming a first connection electrode on the first substrate, and forming a second connection electrode on the light emitting elements;
removing the first substrate and, then, forming a color adjustment layer by injecting a color adjustment material into the third semiconductor layer; and
forming a first electrode configured to contact side surfaces of the first semiconductor layer and the color adjustment layer and to enclose the organic layer.

14. The method according to claim 13, wherein the semiconductor material layer comprises:
the third semiconductor layer;
the first semiconductor layer on the third semiconductor layer;
an active layer on the first semiconductor layer; and
a second semiconductor layer on the active layer.

15. The method according to claim 13, further comprising forming a porous structure by etching the third semiconductor layer before the forming of the light emitting elements.

16. The method according to claim 13, wherein the first electrode contacts the first connection electrode.

17. The method according to claim 13, wherein the organic layer comprises a flexible organic material.

18. The method according to claim 13, wherein the forming of the insulating layer further comprises removing a portion of the insulating layer that contacts the organic layer.

19. The method according to claim 13, further comprising forming a passivation layer on the color adjustment layer and the first electrode.

20. The method according to claim 13, wherein the light emitting elements are configured to emit a third color of light, and
wherein the forming of the color adjustment layer comprises:
forming a first color adjustment layer by injecting a first color adjustment material into the third semiconductor layer in a first emission area, the first color adjustment material being configured to convert the third color of light to a first color of light;
forming a second color adjustment layer by injecting a second color adjustment material into the third semiconductor layer in a second emission area, the second color adjustment material being configured to convert the third color of light to a second color of light; and
forming a third color adjustment layer by injecting a third color adjustment material into the third semiconductor layer in a third emission area, the third color adjustment material being configured to allow the third color of light to pass through the third color adjustment layer.
